(19) United States
(12) Patent Application Publication
(10) Pub. No.: US 2011/0149592 A1
(43) Pub. Date: Jun. 23, 2011

(54) LIGHT COLLECTOR FOR A WHITE LIGHT LED ILLUMINATOR

(76) Inventors: Alexander N. Artsyukhovich, San Juan Capistrano, CA (US); Mikhail Boukhny, Laguna Niguel, CA (US); Ronald T. Smith, Irvine, CA (US); Christopher Horvath, Lake Forest, CA (US)

(21) Appl. No.: 12/961,946

(22) Filed: Dec. 7, 2010

Related U.S. Application Data
(60) Provisional application No. 61/288,949, filed on Dec. 22, 2009.

(51) Int. Cl. H01L 33/00

(52) U.S. Cl. 362/555

(57) ABSTRACT

A white light source includes a light-emitting diode (LED) configured to emit white light in an angular distribution. The white light source further includes a light guide and a light collector configured to collect light across the angular distribution. The light collected by the light collector contributes to a total luminous flux of the white light coupled into the light guide.

This application claims priority to U.S. provisional application Serial No. 61/288,949, filed on Dec. 22, 2009, the contents which are incorporated herein by reference.

### FIELD OF THE INVENTION

This invention relates to white-light illumination sources, and, more particularly to a light collector for a White light LED illuminator.

### BACKGROUND OF THE INVENTION

Light-emitting diodes (LEDs) are desirable for generating white-light illumination in that they consume considerably less energy than comparable light sources, But there are also drawbacks to the use of LEDs that can make them undesirable as light sources in optical fiber illuminators, such as ophthalmic endoilluminators. One of the most significant drawbacks is the wide range of emission angle. White-light LEDs typically include a yellow phosphor cap that converts blue light to white light and, in most cases, a dome lens that collimates white light emitted by the LED. Because of the large area of the LED, it acts an extended light source such that the degree of light collimation is limited and the light is emitted over a large solid angle. This makes it difficult to couple the light from the LED into optical fibers or other light guides. What light can be coupled into the light guide is typically not bright enough to provide adequate illumination. Accordingly, there remains a need for a light source that can be coupled into a fiber while still providing the energy efficiency characteristic of LED light sources.

### BRIEF SUMMARY OF THE INVENTION

In certain embodiments of the present invention, a white light source includes a light-emitting diode (LED) configured to emit white light in an angular distribution. The white light source further includes a light guide and a light collector configured to collect light across the angular distribution. The light collected by the light collector contributes to a total luminous flux of the white light coupled into the light guide.

In particular embodiments of the present invention, the light collector includes a central collimator, an outer parabolic reflector, and a condensing lens focusing collimated light from the central collimator onto the light guide.

In particular embodiments of the present invention, the light collector includes a central collimator extending across a first portion of the angular distribution, a ring-shaped spherical mirror reflecting light in a second portion of the angular distribution outside the first portion, and a condensing lens focusing collimated light from the central collimating lens into the light guide.

In particular embodiments of the present invention, the light guide is a distal light guide and the light collector includes a proximal light guide. The proximal light guide has a proximal end abutting the LED and also includes a reflective material at a distal end reflecting light back from the second light guide to the LED.

Other objects, features and advantages of the present invention will become apparent with reference to the drawings, and the following description of the drawings and claims.

### BRIEF DESCRIPTION OF THE DRAWINGS

FIG. 1 illustrates a white light source including a light collector according to a particular embodiment of the present invention;

FIG. 2 illustrates a white light source including a light collector according to another embodiment of the present invention; and

FIG. 3 illustrates a white light source including a proximal light guide and a distal light guide according to yet another embodiment of the present invention.

### DETAILED DESCRIPTION OF THE INVENTION

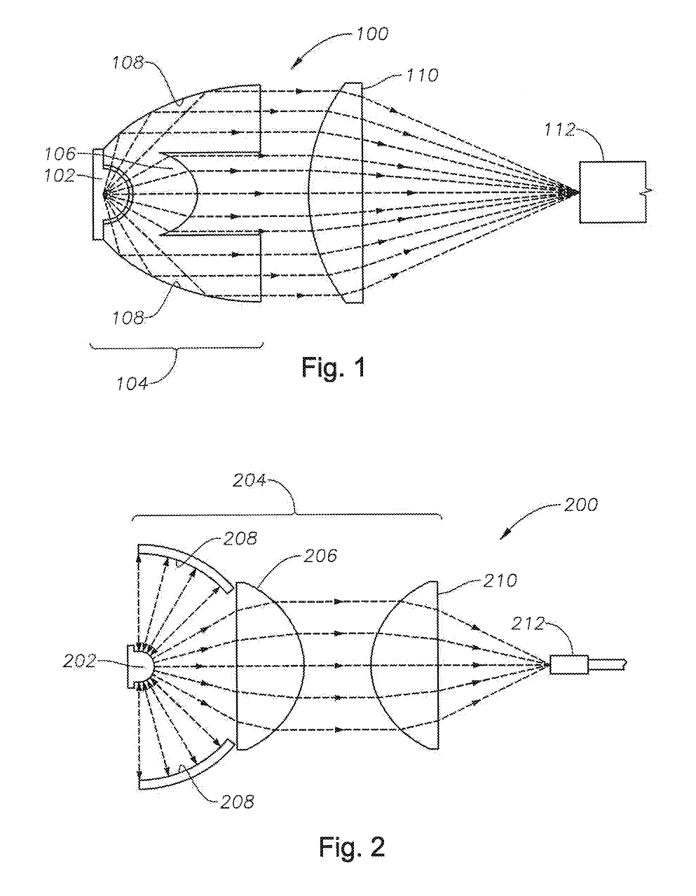

FIG. 1 illustrates a white light source 100 according to a particular embodiment of the present invention. For purposes of this specification, “white light” refers to any light produces by a combination of wavelengths over a substantial range of the visible spectrum, either by a continuum of light wavelengths or by a combination of specific wavelengths, including but not limited to red, green, and blue wavelengths. The white light source 100 includes a light-emitting diode (LED) 102 configured to emit white light. The LED 102 may be a diode material emitting multiple wavelengths that combine to form white light when powered by an electrical power source. Alternatively, the LED 102 may be a diode emitting light of a certain wavelength surrounded by one or more phosphor materials, so that the phosphor and/or LED emit multiple wavelengths that combine into white light.

The LED 102 is surrounded on an emission side by a light collector 104. In the depicted embodiment, the light collector 104 includes a central collimating lens 106 and an outer parabolic reflector 108. As the LED 102 emits white light across a wide angular distribution, the central collimating lens 106 collimates light emitted in the central region of the angular distribution, while the parabolic reflector 108 reflects back light rays emitted outside of the central region to produce parallel beam paths surrounding the central collimated beam. Both the collimated beam from the central collimating lens 106 and the parallel rays from the parabolic reflector 108 then travel to a condensing lens 110, which focuses the light onto a light guide 112. Thus, the white light from the LED 102 emitted over a broad angular distribution is collected and coupled into the light guide 112 efficiently, so that the luminous flux of the white light coupled into the fiber is sufficiently high to provide effective illumination.

FIG. 2 illustrates a white light source 200 according to another embodiment of the present invention. In the depicted embodiment, a white light LED 202 is surrounded on an emission side by a light collector 204, which includes a central collimating lens 206 and a curved mirror 208. The curved mirror 208 is configured to redirect light outside of the angular range covered by the central collimating lens 206, allowing the light energy to be recycled by the LEI) 202, which in turn produces an overall increase in luminous flux through the central collimating lens 206 relative to allowing the light to escape. Advantageously, the curvature of the mirror 208 can be selected to redirect a maximum portion of the light back to the LED 202, such as by making the mirror 208 spherical. Likewise, the mirror 208 can be a dichorie mirror to maximize the intensity of reflected light and to mitigate loss of light due to absorption and interference. A condensing lens 210 focuses collimated light emitted by the central collimating lens 206 onto the light guide 212.

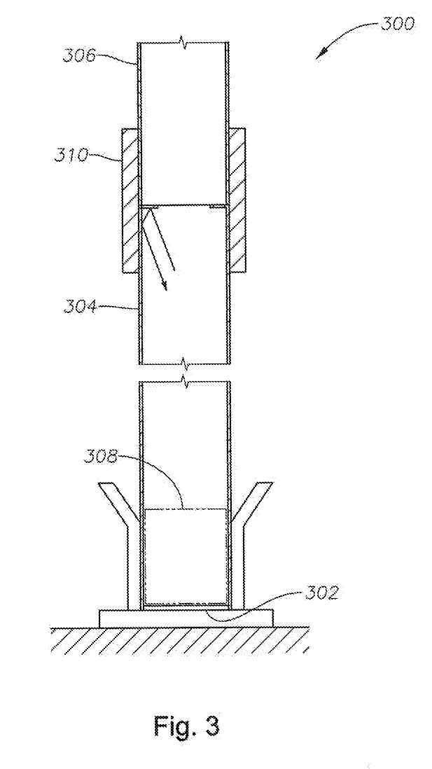

FIG. 3 illustrates a white light source 300 according to yet another embodiment of the present invention. In the depicted embodiment, a white light LEI) 302 is an LED semiconductor chip. The LED semiconductor chip may be, for example, a semiconductor junction emitting blue light covered with a yellow phosphor layer so that the combination of blue light emitted by the semiconductor junction and yellow light from the phosphor appears white. In the illustrated embodiment, a proximal light guide 304 with a proximal end abutting the LED 302 serves as a light collector. The proximal end may be secured to the LED 302, for example, with an optical adhesive and/or a mechanical guide. Light from the proximal light guide 304 is coupled into a distal light guide 306, which is used to carry light from the white light source 300 to the area to be illuminated. The proximal light guide 304 may include a reflective material 308 that captures light emitted from the LED 302 at portions of the proximal light guide 304 in contact with other materials than air. This prevents light loss at boundaries of the light guide 304 where light would not be contained by total internal reflection, in turn allowing the reflected light to be recycled by the LED 302. Preferably, the reflective material can be at least 97% reflective to allow substantially all of the white light from the LED 302 to be collected. For example, the reflective material 308 can be highly polished silver.

The proximal light guide 304 may advantageously configured to allow the LED 302 to be coupled more easily to the proximal light guide 304 than the distal light guide 306. In the depicted embodiment, an optical coupling interface 310 between the proximal light guide 304 and the distal light guide 306 transitions between the different sizes of the light guides 304 and 306. In particular embodiments, this region may also be enclosed. with a reflective material., such as the reflective material 308 used at the proximal end of the proximal light guide 304, in turn allowing light that does not enter the distal light is guide 306 to return through the proximal light guide 304 to be recycled by the LED 302. In such an embodiment, the reflective material can also extend along the entire length of the proximal light guide 304, so that, for example, the proximal light guide 304 could be a hollow glass light guide lines on the inside with silver. To further improve the efficiency of the white light source 300, mirror 310 having a central aperture can also be placed over the LED 302, so that light not emitted into the proximal light guide 304 is reflected back onto the LED 302 and energy from light that would otherwise escape is recycled by the LED 302.

The present invention is illustrated herein by example, and various modifications may be made by a person of ordinary skill in the art. Although the present invention is described in detail, it should be understood that various changes, substitutions and alterations can be made hereto without departing from the scope of the invention as claimed.

What is claimed is:

1. A white light source, comprising:
a light-emitting diode (LED) configured to emit white light in an angular distribution;
a light guide; and
a light collector configured to collect light across the angular distribution such that the light collected by the light collector contributes to a total luminous flux of the white light coupled into the light guide.

2. The white light source of claim 1, wherein the light collector comprises a central collimator, an outer parabolic reflector, and a condensing lens focusing collimated light from the central collimator onto the light guide.

3. The white light source of claim 1, wherein the light collector comprises a central collimator extending across a first portion of the angular distribution, a ring-shaped spherical mirror reflecting light in a second portion of the angular distribution outside the first portion, and a condensing lens focusing collimated light from the central collimating lens into the light guide.

4. The white light source of claim 1, wherein the light guide is a distal light guide and the light collector comprises a proximal light guide, the proximal light guide comprising a proximal end abutting the LED and further comprising a reflective material at a distal end reflecting light back from the second light guide to the LED.

5. The white light source of claim 4, wherein the LED comprises a rectangular LED chip, the first light guide comprises an optical fiber, and the second light guide comprises a rectangular light guide.

6. The white light source of claim 4, wherein the reflective material has a reflectance of at least 97 percent.

7. The white light source of claim 4, wherein the reflective material is silver.

8. The white light source of claim 4, wherein the proximal end of the second light guide is coupled to the LED using optical adhesive.

9. The white light source of claim 4, wherein the proximal end of the second light guide further comprises a mirror having a central aperture, the central aperture admitting light in a first portion of the angular distribution and the mirror reflecting the white light emitted by the LED in a second portion of the angular distribution outside the first portion.
